(19) United States
(12) Patent Application Publication
(10) Pub. No.: US 2009/0163021 A1
(43) Pub. Date: Jun. 25, 2009

(54) Method of Fabricating Semiconductor Device

(76) Inventor: Sang Wook RYU, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/340,300

(22) Filed: Dec. 19, 2008

(30) Foreign Application Priority Data
Dec. 21, 2007 (KR) 10-2007-0134830

(51) Int. Cl. H01L 21/311; H01L 21/3213

(52) U.S. Cl. 438/636; 438/700; 257/E21.305

(57) ABSTRACT

Provided is a method of fabricating a semiconductor device with a dual damascene pattern. According to the method, a diffusion barrier layer, dielectric, a capping layer, and an organic bottom anti-reflection coating (BARC) are sequentially formed on a substrate where a metal interconnection is formed. A photoresist pattern on the organic BARC is formed and the organic BARC, the capping layer, and the dielectric are selectively etched to form a trench using the photoresist pattern as a mask. The photoresist pattern and the organic BARC are removed, and a byproduct capping mask is formed by reacting the capping layer with a reaction gas to form a byproduct. A portion of the trench is filled with the byproduct. Then, a via hole is formed in the trench using the byproduct capping mask as a mask, and the byproduct capping mask, the diffusion barrier layer, and the capping layer are removed.

### CROSS-REFERENCE TO RELATED APPLICATIONS

The present application claims priority under 35 U.S.C. § 119(e) of Korean Patent Application No. 10-2007-0134830 (filed on Dec. 21, 2007), which is hereby incorporated by reference in its entirety.

### BACKGROUND

Embodiments relate to a method of fabricating a semiconductor device with a dual damascene pattern.

Motivation for developing a semiconductor manufacturing technique is to achieve a high degree of integration and high performance of the semiconductor device.

To accomplish a high degree of integration and high performance, a copper wiring process has been studied. However, since copper is not completely etched as a general etching material, a damascene method is mainly used for the copper wiring process. According to the damascene method, an interlayer dielectric is etched first, and then copper is deposited for filling the etched dielectric. A planarization process is then performed to form copper wiring.

### SUMMARY

Embodiments of the present disclosure provide a method of fabricating a semiconductor device which is capable of overcoming misalignment of a hole and a trench due to limitations of exposure equipment by forming a self aligned damascene pattern.

In one embodiment, a method of fabricating a semiconductor device comprises: sequentially forming a diffusion barrier layer, dielectric, a capping layer, and an organic bottom anti-reflection coating (BARC) on a substrate where a metal interconnection is formed; forming a photoresist pattern on the organic BARC and selectively etching the organic BARC, the capping layer, and the dielectric to form a trench using the photoresist pattern as a mask; removing the photoresist pattern and the organic BARC; forming a capping mask by reacting the capping layer with a reaction gas and filling a portion of the trench a the byproduct thereof; forming a via hole in the trench by using the byproduct capping mask as a mask; and removing the byproduct capping mask and then removing the diffusion barrier layer and the capping layer.

The details of one or more embodiments are set forth in the accompanying drawings and the description below. Other features will be apparent from the description and drawings, and from the claims.

### BRIEF DESCRIPTION OF THE DRAWINGS

FIGS. 1 through 7 are cross-sectional views illustrating an exemplary method of fabricating a semiconductor device according to embodiments of the invention.

### DETAILED DESCRIPTION OF THE EMBODIMENTS

Hereinafter, a method of fabricating a semiconductor device according to exemplary embodiments will be described in detail with reference to the accompanying drawings.

It will also be understood that when a layer (or film) is referred to as being ‘on’ another layer or substrate, it can be directly on the other layer or substrate, or intervening layers may also be present.

In the figures, the thickness or dimension of layers and regions may be exaggerated for clarity of illustration. In addition, the sizes of the elements and the relative sizes between elements may be exaggerated for further understanding of the present invention.

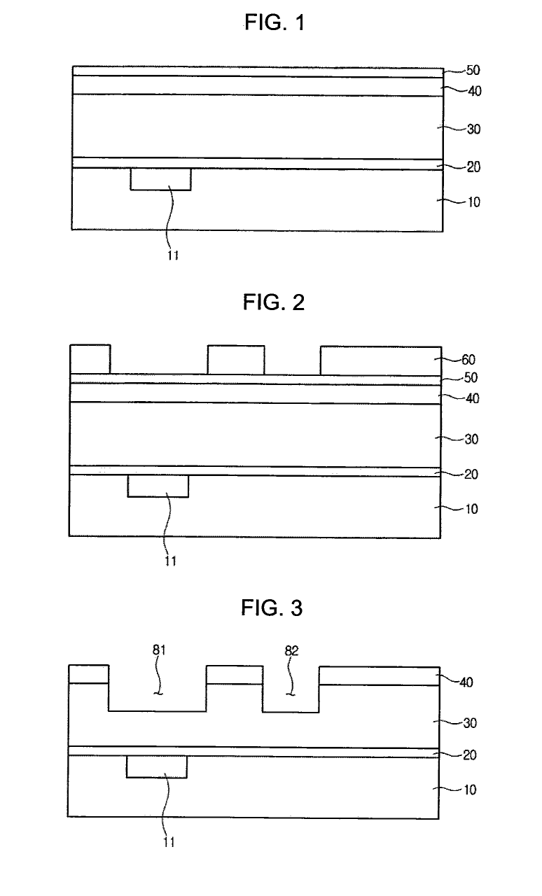

FIGS. 1 through 7 are cross-sectional views illustrating a method of fabricating a semiconductor device according to embodiments of the invention.

Referring to FIG. 1, a lower metal interconnection 11 having an arbitrary pattern is formed in or on a substrate 10 through a series of processes such as a depositing process, an etching process, and so forth. Here, the substrate 10 may comprise an interlayer dielectric on a semiconductor substrate where one or more transistors (not shown) are formed.

A diffusion barrier layer 20 is formed on the substrate 10 where the lower metal interconnection 11 is formed, through a depositing process such as chemical vapor deposition.

The diffusion barrier layer 20 may comprise SiC or SiN with a thickness of 100 Å to 2000 Å.

Moreover, an interlayer dielectric 30 is formed on the diffusion barrier layer 20 with a thickness of 3000 Å to 30000 Å. The interlayer dielectric 30 may comprise fluorine-doped silicate glass (FSG) or an organosilicate glass (OSG).

A capping layer 40 is formed on the interlayer dielectric 30. The capping layer 40 may have at least a single layer structure including a nitride layer, an oxynitride layer, a layer of SiC, or a multi-layered structure thereof. The capping layer 40 may have a thickness of 500 Å to 1500 Å. If the capping layer 40 comprise a silicon nitride layer (SiN) or a silicon oxynitride layer (SiON), the thickness of the organic bottom anti-reflection coating (BARC) 50, which may be formed in the next process, can be reduced due to an anti-reflection effect of the capping layer 40.

The organic BARC 50 may be formed on the capping layer 40 with a thickness of 500 Å to 900 Å.

Referring to FIG. 2, a photoresist is coated on an entire surface of the organic BARC 50 and then patterned to form a photoresist pattern 60.

Referring to FIG. 3, using the photoresist pattern 60 as a mask, the organic BARC 50, the capping layer 40, and the interlayer dielectric 30 are selectively etched to form a trench.

In this embodiment, a first trench 81 and a second trench 82 are formed. The first trench 81 is used for forming a via hole and a metal interconnection, and the second trench 82 is used for forming a metal interconnection.

The organic BARC 50, the capping layer 40, and the interlayer dielectric 30 are etched using O₂ and/or CₓH_{y}F_{z} (where x is a natural number, preferably 1-5, at least one of y and z is a natural number, preferably such that y+z=2x−2, 2x or 2x+2, and y is preferably from 0 to x) as a main etching gas, depending on the material being etched. A trench having a depth of 3000 Å to 5000 Å is formed.

For example, using the photoresist pattern 60 as a mask, the organic BARC 50 and the capping layer 40 are selectively etched. The organic BARC 50 can be etched using O₂, N₂, He, Ar, SO₂, HBr, CₓH_{y}F_{z} or a mixed gas thereof. The capping layer 40 uses CₓH_{y}F_{z} as a main etching gas and also may be etched by adding at least one of O₂, N₂, He, and Ar.

Next, using the photoresist pattern 60, the organic BARC 50, and the capping layer 40 as an etching mask, the interlayer dielectric 30 is selectively etched to form the first trench 81 and the second trench 82. The interlayer dielectric 30 may be etched using O₂, N₂, He, Ar, SO₂, HBr, CₓH_{y}F_{z} or a mixed gas thereof. For example, when the first trench 81 and the second trench 82 are formed, CₓH_{y}F_{z} gas may be used in which a ratio of y and z with respect to x is small (or large).

In more detail, etching conditions include a pressure of 5 mT to 200 mT, a source power of 1000 W to 2000 W, and a bias power of 500 W to 2000 W, the first trench 81 and the second trench 82 can be formed using at least one of CF₄ at a flow rate of 5 sccm to 500 sccm, CHF₃ at a flow rate of 5 sccm to 300 sccm, and CH₂F₂ at a flow rate of 1 sccm to 100 sccm, together with O₂ at a flow rate of 1 sccm to 100 sccm.

Next, the photoresist pattern 60 is removed using oxygen and/or nitrogen gas. In one embodiment, the photoresist pattern 60 and the organic BARC 50 are removed using oxygen gas.

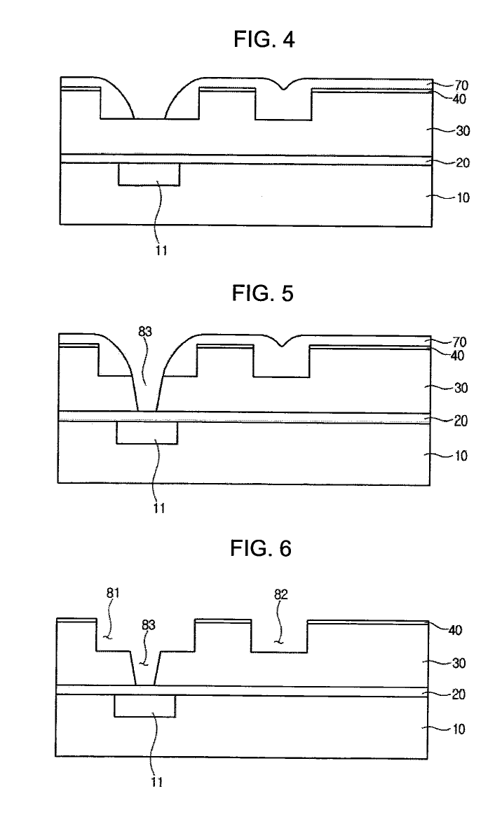

Referring to FIG. 4, the capping layer 40 on the interlayer dielectric 30 reacts with a reaction gas to generate a byproduct, and a portion of the first trench 81 and the second trench 82 are filled with the byproduct to form a byproduct capping mask 70.

The reaction gas comprises HBr or CₓH_{y}F_{z} as a main reaction gas, and at least one of O₂ and Ar may be further added.

For example, when using HBr as a main reaction gas, the byproduct capping mask 70 can be formed under conditions including a pressure of 1 mT to 1000 mT, a source power of 100 W to 900 W, a bias power of 20 W to 300 W, HBr at a flow rate of 10 sccm to 1000 sccm, O₂ at a flow rate of 0 sccm to 100 sccm, and Ar at a flow rate of 0 sccm to 500 sccm. Here, O₂ and Ar may not be used. The byproduct capping mask 70 may have a formula including Si, H, Br, and optionally N.

Alternatively, when using CₓH_{y}F_{z} as a main reaction gas, the byproduct capping mask 70 can be formed under conditions including a pressure of 5 mT to 1000 mT, a source power of 1000 W to 3000 W, a bias power of 0 W to 3000 W, C₅F₈ at a flow rate of 10 sccm to 1000 sccm, O₂ at a flow rate of 0 sccm to 100 sccm, and Ar at a flow rate of 0 sccm to 1000 sccm. Here, the bias power may not be applied, and O₂ and Ar may not be used. When using CₓH_{y}F_{z} gas, the ratio of y and z with respect to x may be small. In more detail, C₄F₈ gas or C₄F₆ gas may be used besides C₅F₈ gas.

Referring to FIG. 5, a via hole 83 is formed by using the byproduct capping mask 70 as an etch mask.

The self aligned via hole 83 may be formed, penetrating a bottom portion of the first trench 81 where the byproduct capping mask 70 is partially formed. However, a via hole is not formed in the second trench 82 because the byproduct capping mask 70 is formed on an entire surface of the second trench 82. The via hole 83 can be formed by etching using CₓH_{y}F_{z} gas and/or O₂ gas.

In more detail, the via hole 83 can be formed using at least one of CF₄ at a flow rate of 5 sccm to 500 sccm, CHF₃ at a flow rate of 5 sccm to 300 sccm, and CH₂F₂ at a flow rate of 1 sccm to 100 sccm, and also O₂ at a flow rate of 1 sccm to 100 sccm as an etching gas under conditions including a pressure of 5 mT to 2000 mT, a source power of 1000 W to 2000 W, and a bias power of 500 W to 2000 W.

Referring to FIG. 6, the byproduct capping mask 70 is removed using an etching gas including O₂ and/or N₂ gas.

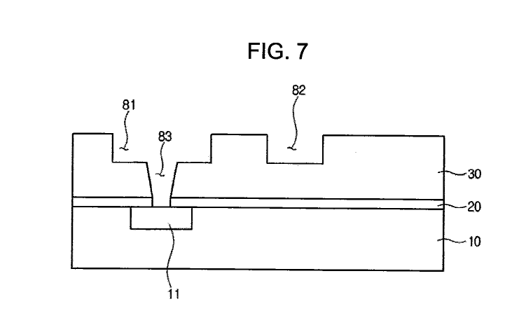

Referring to FIG. 7, the diffusion barrier layer 20 and the capping layer 40 are removed by using CₓH_{y}F_{z} as a main reaction gas, and additionally, at least one of O₂ and Ar. In more detail, the C₅F₈, C₄F₈, or C₄F₆ gas can be used.

Although not illustrated in the accompanying drawings, copper is deposited for filling the first trench 81, the second trench 82, and the via hole 83. Then, a planarization process (e.g., chemical mechanical polishing) is performed to form copper wiring.

According to the method of fabricating a semiconductor device, when forming the trench and the via hole, a self aligned via hole is formed using a byproduct capping mask. Therefore, misalignment of a via hole and a trench due to limitations of exposure (e.g., photolithography) equipment can be overcome.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device, the method comprising:
sequentially forming a diffusion barrier layer, dielectric layer, a capping layer, and an organic bottom anti-reflection coating (BARC) on a substrate;
forming a photoresist on the organic BARC and selectively etching the organic BARC, the capping layer, and the dielectric to form a trench using the photoresist pattern as a mask;
removing the photoresist pattern and the organic BARC;
reacting the capping layer with a reaction gas in order to fill a portion of the trench with the byproduct to form a byproduct capping mask;

2. The method according to claim 1, wherein the diffusion barrier layer comprises of SiC or SiN.

3. The method according to claim 1, wherein the capping layer has a thickness of 500 Å to 1500 Å.

4. The method according to claim 1, wherein the organic BARC is etched using O₂, N₂, He, Ar, SO₂, HBr, CₓH_{y}F_{z} or a mixture thereof.

5. The method according to claim 1, wherein the capping layer is etched using CₓH_{y}F_{z} gas and at least one of O₂, N₂, He, and Ar.

6. The method according to claim 1, wherein the dielectric is etched using O₂, N₂, He, Ar, SO₂, HBr, CₓH_{y}F_{z} or a mixture thereof.

7. The method according to claim 1, wherein the reaction gas comprises HBr or CₓH_{y}F_{z} gas.

8. The method according to claim 1, wherein the byproduct capping mask is removed using a gas including O₂ and/or N₂ gas.

9. The method according to claim 1, wherein the diffusion barrier layer has a thickness of 100 Å to 2000 Å.

10. The method according to claim 1, wherein the capping layer comprises a nitride layer, an oxynitride layer, a layer including SiC, or a multi-layered structure thereof.

11. The method according to claim 7, wherein the reaction gas further comprises at least one of O₂ and Ar.

12. The method according to claim 1, wherein the organic BARC, the capping layer, and the dielectric are etched using O₂ and/or CₓH_{y}F_{z}.

13. The method according to claim 12, wherein x is from 1 to 5, y is from 0 to x, and y+z is 2x−2 or 2x or 2x+2.

14. The method according to claim 13, wherein y is from 0 to x.

15. The method according to claim 1, wherein selectively etching the organic BARC, the capping layer, and the dielectric comprises partially etching the dielectric.

16. The method according to claim 1, the byproduct capping mask exposes a portion of a lower most surface of the trench.
